(19) United States
(12) Patent Application Publication
(10) Pub. No.: US 2025/0047286 A1
(43) Pub. Date: Feb. 6, 2025

(54) TRANSISTOR CIRCUIT

(71) Applicant: SONY SEMICONDUCTOR SOLUTIONS CORPORATION, KANAGAWA (JP)

(72) Inventor: TADAYUKI UCHIMURA, KUMAMOTO (JP)

(21) Appl. No.: 18/716,625

(22) PCT Filed: Oct. 18, 2022
(86) PCT No.: PCT/JP2022/038766

§ 371 Date: Jun. 5, 2024

(30) Foreign Application Priority Data
Dec. 13, 2021 (JP) 2021-201350

(51) Int. Cl. H03K 19/0185; H03K 19/003; H03K 19/018

(52) U.S. Cl. CPC H03K 19/018528; H03K 19/00323; H03K 19/01812

(57) ABSTRACT

A differential delay between a non-inverted output and an inverted output of a transistor circuit is reduced.

A transistor circuit includes a first transistor and a second transistor. The first transistor receives an input signal as an input, and outputs a first output signal. The second transistor receives the input signal as an input, and outputs a second output signal, which is in a reverse polarity with respect to the first output signal, on the basis of a bias that causes the second transistor to operate in a complementary manner with respect to the first transistor. The first transistor may include a first terminal, a second terminal, and a first control terminal that controls a current that flows between the first terminal and the second terminal. The second transistor may include a third terminal, a fourth terminal, and a second control terminal that controls a current that flows between the third terminal and the fourth terminal. The first output signal may be output from the first terminal, the second output signal may be output from the third terminal, and the input signal may be input to the second terminal of the first transistor and the second control terminal of the second transistor.

### TECHNICAL FIELD

The present technology relates to transistor circuits. More particularly, the present technology relates to transistor circuits capable of generating a differential output.

### BACKGROUND ART

In electronic devices and electronic equipment, data are occasionally transferred via an interface circuit that supports the standard of the electronic devices and electronic equipment. Such an interface circuit occasionally uses a differential output in order to shift the level of a signal along with the data transfer. If there is a large differential delay between a non-inverted output and an inverted output of the differential output, an increase in the speed of the data transfer may be hindered, and therefore it is desirable that the differential delay between the non-inverted output and the inverted output should be small. There is proposed a unit interval restoration circuit that generates an output signal that restores the frequency of an original input signal with ignorable phase distortion in correspondence with an output signal of a level shift circuit, in order to eliminate signal phase distortion caused in the level shift circuit (see PTL 1, for example).

### CITATION LIST

### Patent Literature

### [PTL 1]

JP 2010-119104A

### SUMMARY

### Technical Problem

In the related art discussed above, however, a differential input is used in order to generate a differential output. When the differential input is used, it is necessary to generate an inverted input by an inversion unit inverting a non-inverted input, and therefore a differential delay may be caused between the non-inverted input and the inverted input, increasing a differential delay between a non-inverted output and an inverted output.

The present technology has been made in view of this situation, and an object thereof is to reduce a differential delay between a non-inverted output and an inverted output of a transistor circuit.

### Solution to Problem

The present technology has been made to address the foregoing issue, and a first aspect of the present technology provides a transistor circuit including: a first transistor that receives an input signal as an input and that outputs a first output signal; and a second transistor that receives the input signal as an input and that outputs a second output signal, which is in a reverse polarity with respect to the first output signal, on the basis of a bias that causes the second transistor to operate in a complementary manner with respect to the first transistor. This has the effect of generating outputs in different polarities on the basis of the same input signal.

In the first aspect, the first output signal and the second output signal may be differential output signals. This has the effect of generating a differential output without generating an inverted input from a non-inverted input.

In the first aspect, the first transistor may include a first terminal, a second terminal, and a first control terminal that controls a current that flows between the first terminal and the second terminal; the second transistor may include a third terminal, a fourth terminal, and a second control terminal that controls a current that flows between the third terminal and the fourth terminal; the first output signal may be output from the first terminal; the second output signal may be output from the third terminal; and the input signal may be input to the second terminal of the first transistor and the second control terminal of the second transistor. This has the effect of generating a non-inverted output and an inverted output on the basis of the same input signal.

The first aspect may further include a voltage conversion circuit that includes a first input terminal that receives the first output signal as an input and a second input terminal that receives the second output signal as an input, the voltage conversion circuit converting a current based on a transconductance of the first terminal into a voltage to output the voltage from the first input terminal, and converting a current based on a transconductance of the second transistor into a voltage to output the voltage from the second input terminal. This has the effect of generating a level-shifted differential output.

In the first aspect, the first terminal and the third terminal may each be a drain of a field effect transistor or a collector of a bipolar transistor; the first control terminal and the second control terminal may each be a gate of the field effect transistor or a base of the bipolar transistor; and the second terminal and the fourth terminal may each be a source of the field effect transistor and an emitter of the bipolar transistor. This has the effect of generating a non-inverted output and an inverted output on the basis of the same input signal, also when field effect transistors or bipolar transistors are used.

The first aspect may further include a first bias circuit that biases the first control terminal of the first transistor and the fourth terminal of the second transistor such that a voltage between the second terminal and the first control terminal at a time of generation of a transconductance of the first transistor and a voltage between the fourth terminal and the second control terminal at a time of generation of a transconductance of the second transistor are equal to each other. This has the effect of generating a non-inverted output and an inverted output, also when the same input signal is input to two transistors.

In the first aspect, the first transistor and the second transistor may be field effect transistors, and the transistor circuit may further include a second bias circuit that biases a back gate of the first transistor and a back gate of the second transistor. This has the effect of stably generating a non-inverted output and an inverted output on the basis of the same input signal, also when the same input signal is input to two field effect transistors.

In the first aspect, the first transistor and the second transistor may be N-channel field effect transistors or npn bipolar transistors; the input signal may be given at a CMOS (Complementary Metal Oxide Semiconductor) level between a first ground potential and a first power supply potential; and the first control terminal may be connected to the first power supply potential, and the fourth terminal may be connected to a second ground potential. This has the effect of generating a non-inverted output and an inverted output on the basis of the same input signal, also when the input level is equal to the power supply voltage when N-channel field effect transistors or npn bipolar transistors are used.

In the first aspect, the first transistor and the second transistor may be P-channel field effect transistors or pnp bipolar transistors; the input signal may be given at a CMOS level between a first ground potential and a first power supply potential; and the first control terminal may be connected to the first ground potential, and the fourth terminal may be connected to a second power supply potential. This has the effect of generating a non-inverted output and an inverted output on the basis of the same input signal, also when the input level is equal to the power supply voltage when P-channel field effect transistors or pnp bipolar transistors are used.

In the first aspect, the input signal may be at a level other than a CMOS level; and the first control terminal and the fourth terminal may be connected to a common potential. This has the effect of generating a non-inverted output and an inverted output on the basis of the same input signal, also when the input signal is a weak signal.

In the first aspect, the common potential may be variable. This has the effect of generating a non-inverted output and an inverted output on the basis of the same input signal while rendering the input-output range variable.

In the first aspect, the common potential may be generated on the basis of the input signal. This has the effect of generating a bias for generating a non-inverted output and an inverted output on the basis of the same input signal.

### BRIEF DESCRIPTION OF DRAWINGS

FIG. 1 illustrates an example of the configuration of a level conversion circuit according to a first embodiment.

FIG. 2 illustrates an example of the configuration of a level conversion circuit according to a second embodiment.

FIG. 3 illustrates an example of the configuration of a level conversion circuit according to a third embodiment.

FIG. 4 illustrates an example of the configuration of a level conversion circuit according to a fourth embodiment.

FIG. 5 illustrates an example of the configuration of a level conversion circuit according to a fifth embodiment.

FIG. 6 illustrates an example of the configuration of a level conversion circuit according to a sixth embodiment.

FIG. 7 illustrates an example of the configuration of a level conversion circuit according to a seventh embodiment.

FIG. 8 illustrates an example of the configuration of a level conversion circuit according to an eighth embodiment.

FIG. 9 illustrates an example of the configuration of a level conversion circuit according to a ninth embodiment.

FIG. 10 illustrates an example of the configuration of a level conversion circuit according to a tenth embodiment.

FIG. 11 is a block diagram illustrating an example of the configuration of an interface circuit according to an eleventh embodiment.

FIG. 12 illustrates a differential delay between a non-inverted output and an inverted output as compared with a comparative example.

### DESCRIPTION OF EMBODIMENTS

Modes for carrying out the present technique (hereinafter also referred to as “embodiments”) will be described below. The description will be given in the following order.
1. First embodiment (example in which differential output unit is constituted using N-channel field effect transistors)
2. Second embodiment (example in which voltage conversion unit is constituted using flip-flop)
3. Third embodiment (example in which differential output unit is constituted using N-channel field effect transistors and input signal is at CMOS level)
4. Fourth embodiment (example in which differential output unit is constituted using N-channel field effect transistors and input signal is at level other than CMOS level)
5. Fifth embodiment (example in which differential output unit is constituted using P-channel field effect transistor and input signal is at CMOS level)
6. Sixth embodiment (example in which differential output unit is constituted using P-channel field effect transistor and input signal is at level other than CMOS level)
7. Seventh embodiment (example in which differential output unit is constituted using N-channel field effect transistors, input signal is at level other than CMOS level, and bias is variable)
8. Eighth embodiment (example in which differential output unit is constituted using N-channel field effect transistors, input signal is at level other than CMOS level, and bias is generated from input signal)
9. Ninth embodiment (example of layout in which differential output unit is constituted using N-channel field effect transistors)
10. Tenth embodiment (example in which differential output unit is constituted using npn bipolar transistors)
11. Eleventh embodiment (example in which level conversion circuit is applied to interface)

### 1. First Embodiment

While a level conversion circuit 101 is used as a transistor circuit provided with a differential output unit 112 by way of example in the following embodiments, the transistor circuit provided with the differential output unit 112 may be an operational amplifier, a comparator, a logic circuit, etc., for example.

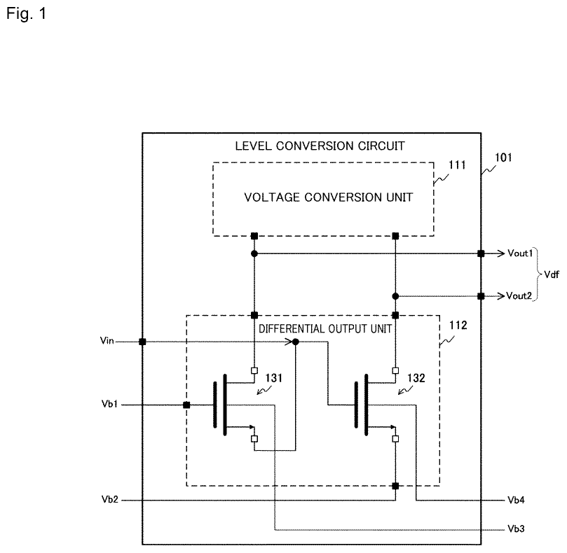

FIG. 1 illustrates an example of the configuration of a level conversion circuit according to a first embodiment.

In the drawing, a level conversion circuit 101 includes a voltage conversion unit 111 and a differential output unit 112. The differential output unit 112 generates a differential output Vdf on the basis of the same input signal Vin.

The differential output unit 112 includes two transistors 131, 132. The transistors 131, 132 are N-channel field effect transistors. The transistor 131 receives the input signal Vin as an input, and outputs an output signal Vout1. The transistor 132 receives the input signal Vin as an input, and outputs an output signal Vout2 on the basis of a bias that causes the transistor 132 to operate in a complementary manner with respect to the transistor 131. The term “complementary” as used herein indicates a relationship in which the drain current of the transistor 132 decreases in accordance with an increase in the drain current of the transistor 131, and in which the drain current of the transistor 132 increases in accordance with a decrease in the drain current of the transistor 131, for example.

At this time, the transistor 131 may generate a transconductance in the reverse polarity with respect to the input signal Vin using the input signal Vin as an input. The transistor 132 may generate a transconductance in the same polarity as the input signal Vin using the input signal Vin as an input.

In order to render the polarities of the transconductances generated by the transistors 131, 132 different from each other, it is possible to input the input signal Vin to different types of terminals, among terminals of the transistors 131, 132 for determining a threshold voltage. For example, the input signal Vin may be input to the source of the transistor 131, and the input signal Vin may be input to the gate of the transistor 132.

The term “transconductance” as used herein indicates variations in the drain current with respect to variations in a gate-source voltage Vgs of the transistor 131, 132. As the transconductance of the transistor 131, 132 is larger, the gain of the transistor 131, 132 is larger. The transconductance is also called a “mutual conductance”.

With a transconductance in the reverse polarity, the drain current decreases when the gate-source voltage Vgs increases, and the drain current increases when the gate-source voltage Vgs decreases. With a transconductance in the same polarity, the drain current increases when the gate-source voltage Vgs increases, and the drain current decreases when the gate-source voltage Vgs decreases.

Here, the output signal Vout2 may be in the reverse polarity with respect to the output signal Vout1. For example, the output signal Vout1 may be an inverted signal, and the output signal Vout2 may be a non-inverted signal. At this time, the output signals Vout1, Vout2 may constitute the differential output Vdf.

The transistor 131 is an example of the first transistor set forth in the claims. The transistor 132 is an example of the second transistor set forth in the claims. The output signal Vout1 is an example of the first output signal set forth in the claims. The output signal Vout2 is an example of the second output signal set forth in the claims.

The source of the transistor 131 is connected to the gate of the transistor 132, and the drains of the transistors 131, 132 are connected to the voltage conversion unit 111. The input signal Vin is input to the source of the transistor 131 and the gate of the transistor 132. A bias voltage Vb1 is input to the gate of the transistor 131, and a bias voltage Vb2 is input to the source of the transistor 132. A bias voltage Vb3 is input to the back gate of the transistor 131, and a bias voltage Vb4 is input to the back gate of the transistor 132. The output signal Vout1 is output from the drain of the transistor 131, and the output signal Vout2 is output from the drain of the transistor 132.

The drain of the transistor 131 is an example of the first terminal set forth in the claims. The source of the transistor 131 is an example of the second terminal set forth in the claims. The gate of the transistor 131 is an example of the first control terminal set forth in the claims. The drain of the transistor 132 is an example of the third terminal set forth in the claims. The source of the transistor 132 is an example of the fourth terminal set forth in the claims. The gate of the transistor 132 is an example of the second terminal set forth in the claims.

The bias voltages Vb1, Vb2 may be set such that the gate-source voltages Vgs at the time of generation of a transconductance of the transistors 131, 132 are equal to each other. The bias voltages Vb3, Vb4 may be set to a ground potential, for example.

At this time, when the transistor 131 receives the input signal Vin as an input, the transistor 131 may generate an output signal Vout1 in the opposite phase to the input signal Vin. When the transistor 132 receives the input signal Vin as an input, the transistor 132 may generate an output signal Vout2 in the same phase as the input signal Vin.

The voltage conversion unit 111 converts the level of the differential output Vdf generated by the differential output unit 112. At this time, the voltage conversion unit 111 may shift the level of the output signal Vout1 by converting a current based on the transconductance of the transistor 131 into a voltage. The voltage conversion unit 111 may shift the level of the output signal Vout2 by converting a current based on the transconductance of the transistor 132 into a voltage. The voltage conversion unit 111 is not limited to being configured to convert a current based on the transconductance of the transistor 131, 132 into a voltage, and may be configured to convert an output voltage of the transistor 131, 132 into a different voltage, for example.

The drain currents of the transistors 131, 132 vary in a complementary manner on the basis of the input signal Vin. The differential output Vdf obtained by shifting the level of the input signal Vin and obtaining a differential for the input signal Vin is generated by the voltage conversion unit 111 operating on the basis of complementary variations in the drain currents of the transistors 131, 132.

In this manner, with the first embodiment discussed above, it is possible to generate output signals Vout1, Vout2 in different polarities from each other on the basis of the same input signal Vin, and to generate a differential output Vdf without generating an inverted input from a non-inverted input. Therefore, it is not necessary to provide an inversion unit that inverts a non-inverted input before the transistor 131 in order to generate a differential output Vdf, suppressing a differential delay between the output signals Vout1, Vout2. Since it is not necessary to provide an inversion unit that inverts a non-inverted input in order to generate a differential output Vdf, it is possible to reduce the size, cost, and power consumption of the level conversion circuit 101.

### 2. Second Embodiment

In the first embodiment discussed above, the differential output unit 112 is constituted using N-channel field effect transistors, and the differential output Vdf is input to the voltage conversion unit 111. In a second embodiment, the voltage conversion unit 111, to which the differential output Vdf is input, is constituted using a flip-flop.

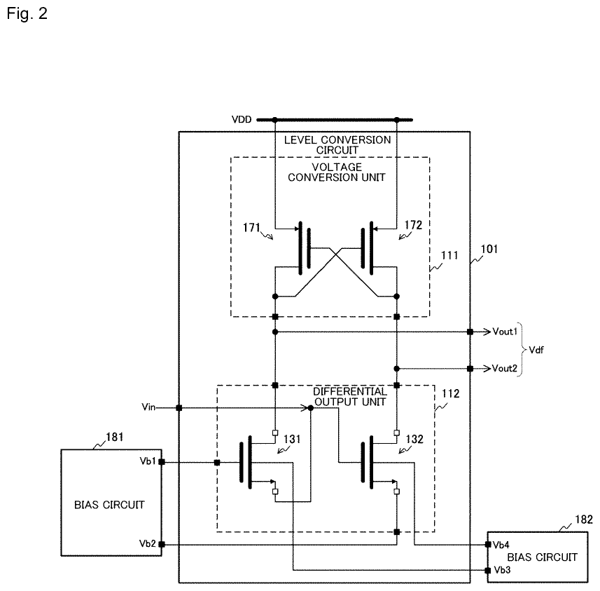

FIG. 2 illustrates an example of the configuration of a level conversion circuit according to a second embodiment.

In the level conversion circuit 101 according to the second embodiment, the voltage conversion unit 111 according to the first embodiment discussed above is provided with two transistors 171, 172. The transistors 171, 172 are P-channel field effect transistors. The gate of the transistor 171 is connected to the drain of the transistor 172, and the gate of the transistor 172 is connected to the drain of the transistor 171. The drain of the transistor 171 is connected to the drain of the transistor 131, and the drain of the transistor 172 is connected to the drain of the transistor 132. The sources of the transistors 171, 172 are connected to a power supply potential VDD. At this time, the transistors 171, 172 may constitute a flip-flop.

The drain of the transistor 171 is an example of the first input terminal set forth in the claims. The drain of the transistor 172 is an example of the second input terminal set forth in the claims.

Bias circuits 181, 182 are provided outside the level conversion circuit 101. The bias circuit 181 supplies bias voltages Vb1, Vb2 to the transistors 131, 132, respectively. The bias circuit 182 supplies bias voltages Vb3, Vb4 to the transistors 131, 132, respectively.

The bias circuit 181 is connected to the gate of the transistor 131 and the source of the transistor 132. The bias circuit 182 is connected to the back gates of the transistors 131, 132.

The drain potentials of the transistors 131, 132 vary in a complementary manner in accordance with the level of the input signal Vin. One of the transistors 171, 172 turns on and the other of the transistors 171, 172 turns off on the basis of complementary variations in the drain potentials of the transistors 131, 132. The drain potential of one of the transistors 171, 172 that has turned on is pulled up to a level obtained by subtracting the source-drain voltage of the one of the transistors 171, 172 from the power supply voltage VDD via the one of the transistors 171, 172, converting the level of the differential output Vdf. At this time, the source-drain voltage of one of the transistors 171, 172 becomes substantially zero when the one of the transistors 171, 172 turns on, and thus the drain potential of the one of the transistors 171, 172 becomes substantially equal to the power supply voltage VDD.

In this manner, in the second embodiment discussed above, the voltage conversion unit 111 which receives the differential output Vdf as an input is constituted using a flip-flop. Consequently, it is possible to pull up the level of the differential output Vdf to a level substantially equal to the power supply voltage VDD on the basis of switching operation of the flip-flop which receives the differential output Vdf as an input, and to convert the level of the differential output Vdf while suppressing an increase in power consumption.

While a flip-flop is used in the second embodiment discussed above as the voltage conversion unit 111 according to the first embodiment discussed above by way of example, the voltage conversion unit 111 may be configured otherwise, and the voltage conversion unit 111 may be constituted using a pull-up resistor, for example.

### 3. Third Embodiment

While the differential output unit 112 is constituted using N-channel field effect transistors in the first embodiment discussed above, the differential output unit 112 is constituted using N-channel field effect transistors when the input signal Vin is at a CMOS level in a third embodiment.

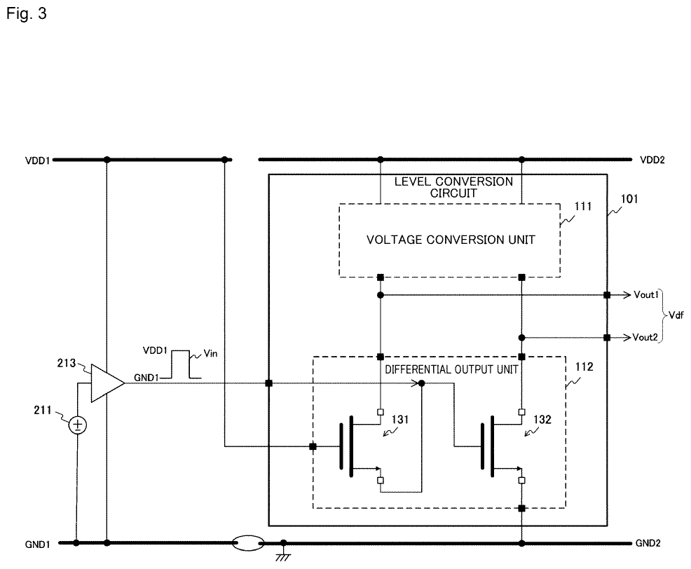

FIG. 3 illustrates an example of the configuration of a level conversion circuit according to a third embodiment. In the drawing, back gate biases of the transistors 131, 132 are not illustrated.

In the third embodiment, a buffer 213 is provided before the differential output unit 112. A signal source 211 is provided before the buffer 213. The buffer 113 converts the output voltage of the signal source 211 to a CMOS level. In order to supply power to the buffer 213, the buffer 213 is connected between a power supply potential VDD1 and a ground potential GND1.

The power supply potential VDD1 is used as the bias voltage Vb1 according to the first embodiment discussed above, and a ground potential GND2 is used as the bias voltage Vb2. At this time, the gate of the transistor 131 is connected to the power supply potential VDD1, and the source of the transistor 132 is connected to the ground potential GND2. Here, the gate-source voltages Vgs at the time of generation of a transconductance of the transistors 131, 132 may be equal to each other. The voltage conversion unit 111 is connected between the differential output unit 112 and the power supply potential VDD2. The power supply potentials VDD1, VDD2 are different from each other. The ground potentials GND1, GND2 may be at the same potential as each other.

The level of the output voltage of the signal source 211 is converted by the buffer 213 to a level between the power supply potential VDD1 and the ground potential GND1, generating the input signal Vin to be input to the source of the transistor 131 and the gate of the transistor 132. The drain currents of the transistors 131, 132 vary in a complementary manner on the basis of the input signal Vin. The differential output Vdf obtained by shifting the level of the input signal Vin and obtaining a differential for the input signal Vin is generated by the voltage conversion unit 111 operating on the basis of complementary variations in the drain currents of the transistors 131, 132. At this time, the voltage conversion unit 111 may convert an input level that matches the power supply potential VDD1 to an output level that matches the power supply potential VDD2.

In this manner, in the third embodiment discussed above, the gate of the transistor 131 is biased on the basis of the power supply potential VDD1, and the source of the transistor 132 is biased on the basis of the ground potential GND2. Consequently, it is possible to generate the differential output Vdf on the basis of the same input signal Vin, also when the input level is at a CMOS level when N-channel field effect transistors are used as the transistors 131, 132.

It is possible to suppress noise of the buffer 213 and noise of the level conversion circuit 101 affecting each other by separating the ground potentials GND1, GND2 for the buffer 213 and the level conversion circuit 101.

### 4. Fourth Embodiment

In the third embodiment discussed above, the differential output unit 112 is constituted using N-channel field effect transistors when the input signal Vin is at a CMOS level. In a fourth embodiment, the differential output unit 112 is constituted using N-channel field effect transistors when the input signal Vin is at a level other than a CMOS level.

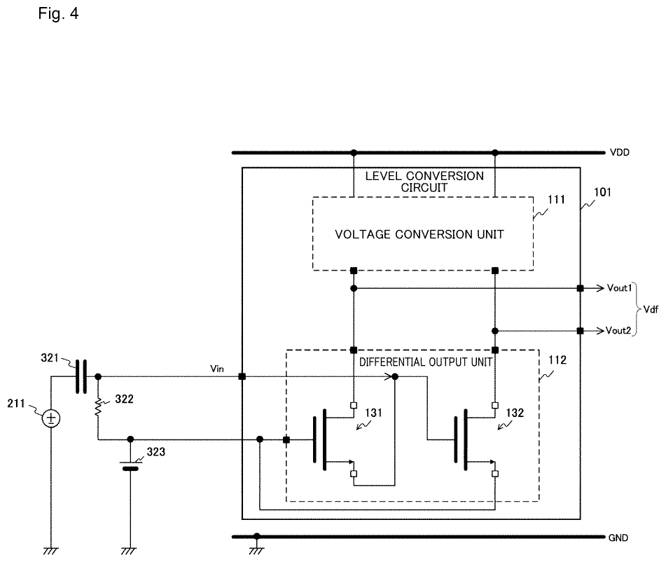

FIG. 4 illustrates an example of the configuration of a level conversion circuit according to a fourth embodiment. In the drawing, back gate biases of the transistors 131, 132 are not illustrated.

In the fourth embodiment, the signal source 211 is provided before the differential output unit 112. The signal source 211 may be connected to the input of the differential output unit 112 via a capacitor 321. A direct current power supply 323 is connected via a resistor 322 between the capacitor 321 and the input of the differential output unit 112. At this time, the capacitor 321 and the resistor 322 may constitute a high-pass filter.

A common potential generated by the direct-current power supply 323 is used as the bias voltages Vb1, Vb2 according to the first embodiment discussed above. At this time, the gate of the transistor 131 and the source of the transistor 132 are connected to the direct current power supply 323. A battery may be used as the direct-current power supply 323, for example. Here, the gate-source voltages Vgs at the time of generation of a transconductance of the transistors 131, 132 may be equal to each other. The voltage conversion unit 111 is connected between the differential output unit 112 and the power supply potential VDD.

The output voltage of the signal source 211 is input as the input signal Vin to the source of the transistor 131 and the gate of the transistor 132 via the capacitor 321. The drain currents of the transistors 131, 132 vary in a complementary manner on the basis of the input signal Vin. The differential output Vdf obtained by shifting the level of the input signal Vin and obtaining a differential for the input signal Vin is generated by the voltage conversion unit 111 operating on the basis of complementary variations in the drain currents of the transistors 131, 132. At this time, the voltage conversion unit 111 may convert an input level of the signal source 211 to an output level that matches the power supply potential VDD.

In this manner, in the fourth embodiment discussed above, the gate of the transistor 131 and the source of the transistor 132 are biased on the basis of the voltage of the direct-current power supply 323. Consequently, it is possible to generate the differential output Vdf on the basis of the same input signal Vin, also when the input level is at a weal signal level when N-channel field effect transistors are used as the transistors 131, 132.

### 5. Fifth Embodiment

In the third embodiment discussed above, the differential output unit 112 is constituted using N-channel field effect transistors when the input signal Vin is at a CMOS level. In a fifth embodiment, a differential output unit 412 is constituted using P-channel field effect transistors when the input signal Vin is at a CMOS level.

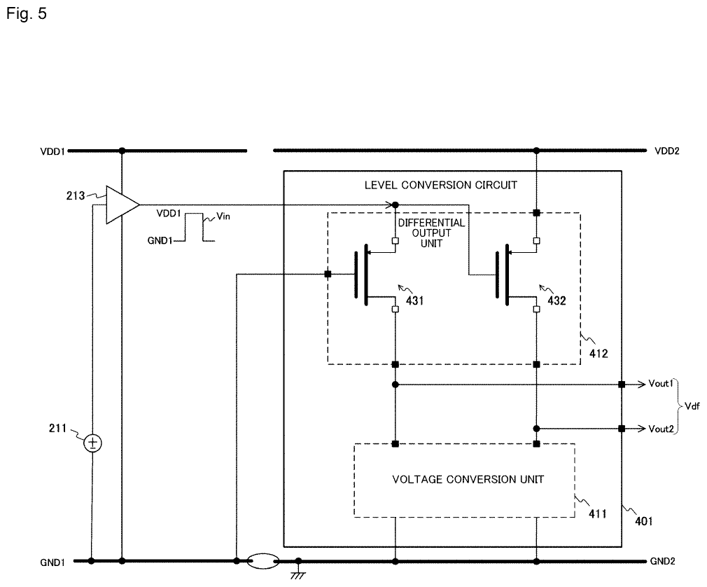

FIG. 5 illustrates an example of the configuration of a level conversion circuit according to a fifth embodiment. In the drawing, back gate biases of the transistors 431, 432 are not illustrated.

In the drawing, a level conversion circuit 401 includes a voltage conversion unit 411 and a differential output unit 412. The differential output unit 412 generates a differential output Vdf on the basis of the same input signal Vin.

The differential output unit 412 includes two transistors 431, 432. The transistors 431, 432 are P-channel field effect transistors. The transistor 431 outputs an output signal Vout1 on the basis of the input signal Vin. The transistor 432 receives the input signal Vin as an input, and outputs an output signal Vout2 on the basis of a bias that causes the transistor 432 to operate in a complementary manner with respect to the transistor 431.

At this time, the transistor 431 may generate a transconductance in the reverse polarity with respect to the input signal Vin using the input signal Vin as an input. The transistor 432 may generate a transconductance in the same polarity as the input signal Vin using the input signal Vin as an input.

In order to render the polarities of the transconductances generated by the transistors 431, 432 different from each other, it is possible to input the input signal Vin to different types of terminals, among terminals of the transistors 431, 432 for determining a threshold voltage. For example, the input signal Vin may be input to the source of the transistor 431, and the input signal Vin may be input to the gate of the transistor 432.

Here, the output signal Vout2 may be in the reverse polarity with respect to the output signal Vout1. At this time, the output signals Vout1, Vout2 may constitute the differential output Vdf.

The transistor 431 is another example of the first transistor set forth in the claims. The transistor 432 is another example of the second transistor set forth in the claims. The output signal Vout1 is another example of the first output signal set forth in the claims. The output signal Vout2 is another example of the second output signal set forth in the claims.

The source of the transistor 431 is connected to the gate of the transistor 432, and the drains of the transistors 431, 432 are connected to the voltage conversion unit 411. The input signal Vin is input to the source of the transistor 431 and the gate of the transistor 432. The output signal Vout1 is output from the drain of the transistor 431, and the output signal Vout2 is output from the drain of the transistor 432.

The ground potential GND1 is used as the bias voltage Vb1 according to the first embodiment discussed above, and the power supply potential VDD2 is used as the bias voltage Vb2. At this time, the gate of the transistor 431 is connected to the ground potential GND1, and the source of the transistor 432 is connected to the power supply potential VDD2. Here, the gate-source voltages Vgs at the time of generation of a transconductance of the transistors 431, 432 may be equal to each other.

The drain of the transistor 431 is another example of the first terminal set forth in the claims. The source of the transistor 431 is another example of the second terminal set forth in the claims. The gate of the transistor 431 is another example of the first control terminal set forth in the claims. The drain of the transistor 432 is another example of the third terminal set forth in the claims. The source of the transistor 432 is another example of the fourth terminal set forth in the claims. The gate of the transistor 432 is another example of the second control terminal set forth in the claims.

The voltage conversion unit 411 converts the level of the differential output Vdf generated by the differential output unit 412. The voltage conversion unit 411 is connected between the differential output unit 412 and the ground potential GND2. At this time, the voltage conversion unit 411 may shift the level of the output signal Vout1 by converting a current based on the transconductance of the transistor 431 into a voltage. The voltage conversion unit 411 may shift the level of the output signal Vout2 by converting a current based on the transconductance of the transistor 432 into a voltage.

The level of the output voltage of the signal source 211 is converted by the buffer 213 to a level between the power supply potential VDD1 and the ground potential GND1, generating the input signal Vin to be input to the source of the transistor 431 and the gate of the transistor 432. The drain currents of the transistors 431, 432 vary in a complementary manner on the basis of the input signal Vin. The differential output Vdf obtained by shifting the level of the input signal Vin and obtaining a differential for the input signal Vin is generated by the voltage conversion unit 411 operating on the basis of complementary variations in the drain currents of the transistors 431, 432.

In this manner, in the fifth embodiment discussed above, the gate of the transistor 431 is biased on the basis of the ground potential GND1, and the source of the transistor 432 is biased on the basis of the power supply potential GND2. Consequently, it is possible to generate the differential output Vdf on the basis of the same input signal Vin, also when the input level is at a CMOS level when P-channel field effect transistors are used as the transistors 431, 432.

### 6. Sixth Embodiment

In the fourth embodiment discussed above, the differential output unit 112 is constituted using N-channel field effect transistors when the input signal Vin is at a level other than a CMOS level. In a sixth embodiment, the differential output unit 112 is constituted using P-channel field effect transistors when the input signal Vin is at a level other than a CMOS level.

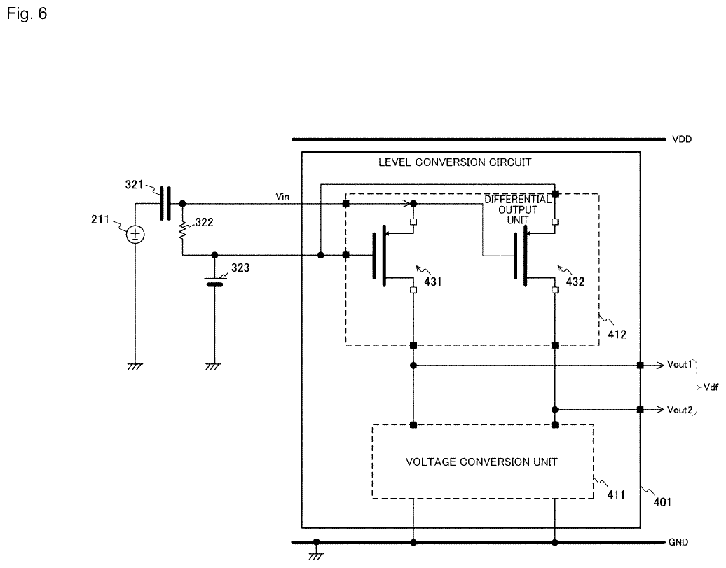

FIG. 6 illustrates an example of the configuration of a level conversion circuit according to a sixth embodiment. In the drawing, back gate biases of the transistors 431, 432 are not illustrated.

In the sixth embodiment, the signal source 211 is provided before a differential output unit 112 via the capacitor 321. A direct-current power supply 323 is connected via a resistor 322 between the capacitor 321 and the input of the differential output unit 112.

A common potential generated by the direct-current power supply 323 is used as the bias voltages Vb1, Vb2 according to the first embodiment discussed above. At this time, the gate of the transistor 431 and the source of the transistor 432 are connected to the direct-current power supply 323. Here, the gate-source voltages Vgs at the time of generation of a transconductance of the transistors 431, 432 may be equal to each other. The voltage conversion unit 111 is connected between the differential output unit 112 and the ground potential GND.

The output voltage of the signal source 211 is input as the input signal Vin to the source of the transistor 431 and the gate of the transistor 432 via the capacitor 321. The drain currents of the transistors 431, 432 vary in a complementary manner on the basis of the input signal Vin. The differential output Vdf obtained by shifting the level of the input signal Vin and obtaining a differential for the input signal Vin is generated by the voltage conversion unit 411 operating on the basis of complementary variations in the drain currents of the transistors 431, 432.

In this manner, in the sixth embodiment discussed above, the gate of the transistor 431 and the source of the transistor 432 are biased on the basis of the voltage of the direct-current power supply 323. Consequently, it is possible to generate the differential output Vdf on the basis of the same input signal Vin, also when the input level is at a weak signal level when P-channel field effect transistors are used as the transistors 431, 432.

### 7. Seventh Embodiment

While the voltage of the direct current power supply 323 is fixed in the fourth embodiment discussed above, the voltage of a direct current power supply 333 is variable in a seventh embodiment.

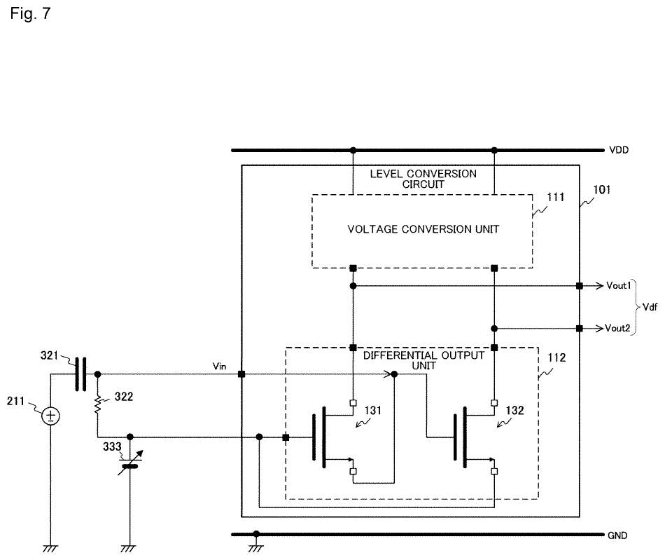

FIG. 7 illustrates an example of the configuration of a level conversion circuit according to a seventh embodiment. In the drawing, back gate biases of the transistors 131, 132 are not illustrated.

A direct-current power supply 333 is provided before the level conversion circuit 101 according to the seventh embodiment, in place of the direct-current power supply 323 according to the fourth embodiment discussed above. The other components provided before the level conversion circuit 101 according to the seventh embodiment are the same as the components provided before the level conversion circuit 101 according to the fourth embodiment discussed above.

In the seventh embodiment, a common potential generated by the direct-current power supply 333 is used as the bias voltages Vb1, Vb2 according to the first embodiment discussed above. At this time, the gate of the transistor 131 and the source of the transistor 132 are connected to the direct-current power supply 333. The voltage of the direct current power supply 333 is variable. Here, the gate-source voltages Vgs at the time of generation of a transconductance of the transistors 131, 132 may be equal to each other.

In this manner, with the seventh embodiment discussed above, it is possible to generate the differential output Vdf on the basis of the same input signal Vin while rendering the input-output range of the differential output unit 112 variable by rendering the voltage of the direct current power supply 333 variable.

### 8. Eighth Embodiment

In the fourth embodiment discussed above, the gate of the transistor 131 and the source of the transistor 132 are biased on the basis of the voltage of the direct-current power supply 323. In an eighth embodiment, the gate of the transistor 131 and the source of the transistor 132 are biased on the basis of a voltage generated from the input signal Vin.

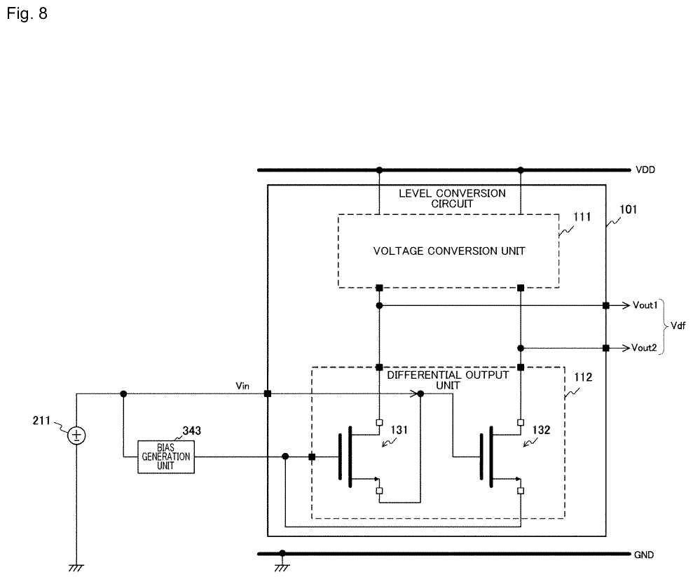

FIG. 8 illustrates an example of the configuration of a level conversion circuit according to an eighth embodiment. In the drawing, back gate biases of the transistors 131, 132 are not illustrated.

A bias generation unit 343 is provided before the level conversion circuit 101 according to the eighth embodiment, in place of the direct-current power supply 323 according to the fourth embodiment discussed above. The capacitor 321 and the resistor 322 according to the fourth embodiment discussed above are omitted from the components provided before the level conversion circuit 101 according to the eighth embodiment. The other components provided before the level conversion circuit 101 according to the eighth embodiment are the same as the components provided before the level conversion circuit 101 according to the fourth embodiment discussed above.

In the eighth embodiment, a common potential generated by the bias generation unit 343 is used as the bias voltages Vb1, Vb2 according to the first embodiment discussed above. At this time, the bias generation unit 343 generates bias voltages for the gate of the transistor 131 and the source of the transistor 132 on the basis of the output voltage of the signal source 211. Here, the bias voltages may vary in accordance with fluctuations in the level of the input signal Vin. At this time, the bias generation unit 343 generates bias voltages so as to be higher than threshold voltages of the transistors 131, 132. The input of the bias generation unit 343 is connected to the signal source 211, and the output of the bias generation unit 343 is connected to the gate of the transistor 131 and the source of the transistor 132. Here, the gate-source voltages Vgs at the time of generation of a transconductance of the transistors 131, 132 may be equal to each other.

In this manner, with the eighth embodiment discussed above, it is possible for the differential output unit 112 to generate the differential output Vdf on the basis of the same input signal Vin, also when bias voltages generated on the basis of the same input signal Vin are used.

### 9. Ninth Embodiment

While the level conversion circuit 101 is constituted using the differential output unit 112 and the voltage conversion unit 111 in the first embodiment discussed above, a level conversion circuit 601 is constituted by integrating a differential output unit 612 and a voltage conversion unit 611 on a semiconductor substrate 600 in a ninth embodiment.

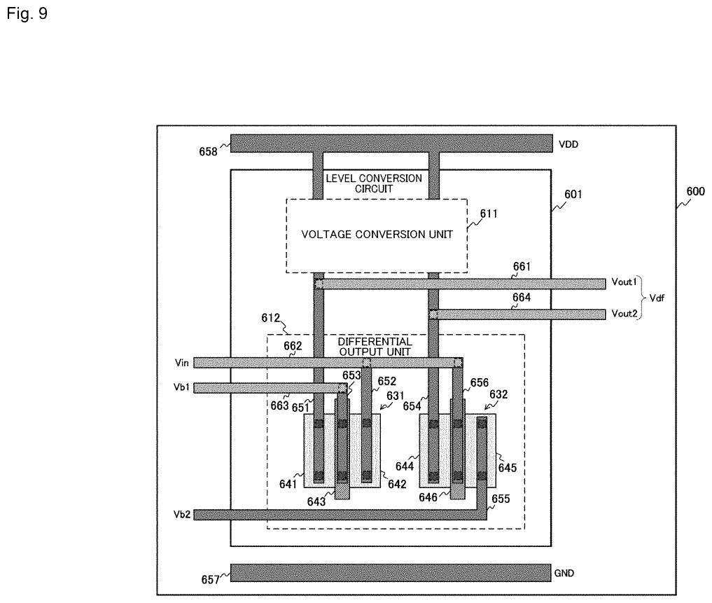

FIG. 9 illustrates an example of the configuration of a level conversion circuit according to a ninth embodiment. In the drawing, back gate biases of the transistors 631, 632 are not illustrated.

In the drawing, a level conversion circuit 601 is formed on a semiconductor substrate 600. The semiconductor substrate 600 may be a single-crystal silicon substrate, or may be a compound semiconductor substrate of GaAn, SiC, GaN, etc. The level conversion circuit 601 includes a voltage conversion unit 611 and a differential output unit 612. The voltage conversion unit 611 and the differential output unit 612 may operate in the same manner as the voltage conversion unit 111 and the differential output unit 112, respectively, in FIG. 1.

In the differential output unit 612, two transistors 631, 632 are formed on the semiconductor substrate 600. The transistor 631 includes impurity diffusion layers 641, 642 and a gate electrode 643. The impurity diffusion layers 641, 642 are formed on the semiconductor substrate 600 as spaced from each other. The gate electrode 643 is formed on a channel region, which is positioned between the impurity diffusion layers 641, 642, via a gate insulating film. The impurity diffusion layer 641 may be used as the drain, and the impurity diffusion layer 642 may be used as the source.

The transistor 632 includes impurity diffusion layers 644, 645 and a gate electrode 646. The impurity diffusion layers 644, 645 are formed on the semiconductor substrate 600 as spaced from each other. The gate electrode 646 is formed on a channel region, which is positioned between the impurity diffusion layers 644, 645, via a gate insulating film. The impurity diffusion layer 644 may be used as the drain, and the impurity diffusion layer 645 may be used as the source.

Here, when the transistors 631, 632 are N-channel field effect transistors, P-type impurities such as B (boron) may be introduced into the semiconductor substrate 600, and N-type impurities such as P (phosphorus) or As (arsenic) may be introduced into the impurity diffusion layers 641, 642, 644, 645.

The impurity diffusion layers 641 to 644 are connected to wires 651 to 654, respectively, and the gate electrodes 643, 646 are connected to wires 653, 656, respectively. The wires 651 to 654 are connected to wires 661 to 664, respectively, and the wire 662 is also connected to the wire 656.

The input signal Vin is applied to the impurity diffusion layer 642 via the wires 662, 652, and applied to the gate electrode 646 via the wires 662, 656. The bias voltage Vb1 is applied to the gate electrode 643 via the wires 663, 653. The bias voltage Vb2 is applied to the impurity diffusion layer 645 via the wire 655. The wires 651, 654 are connected to the voltage conversion unit 611. The output signal Vout1 is output to the outside of the level conversion circuit 601 via the wires 651, 661, and the output signal Vout2 is output to the outside of the level conversion circuit 601 via the wires 654, 664.

A ground line 657 and a power supply line 658 are formed on the semiconductor substrate 600. The potential of the ground line 657 is set to a ground potential GND. The potential of the power supply line 658 is set to a power supply potential VDD. The power supply line 658 is connected to the voltage conversion unit 611. First-layer wires formed on the semiconductor substrate 600 may be used as the wires 651 to 656, the ground line 657, and the power supply line 658. Second-layer wires formed on the first-layer wires may be used as the wires 661 to 664.

In this manner, with the ninth embodiment discussed above, it is possible to generate the differential output Vdf without generating an inverted input from a non-inverted input by forming the two transistors 631, 632 on the semiconductor substrate 600. Therefore, it is possible to reduce the layout area of the differential output unit 112 on the semiconductor substrate 600, and to reduce the size, cost, and power consumption of the level conversion circuit 601, compared to the configuration in which a differential output is generated using a differential input.

### 10. Tenth Embodiment

While the differential output unit 112 is constituted using N-channel field effect transistors in the first embodiment discussed above, a differential output unit 712 is constituted using npn bipolar transistors in a tenth embodiment.

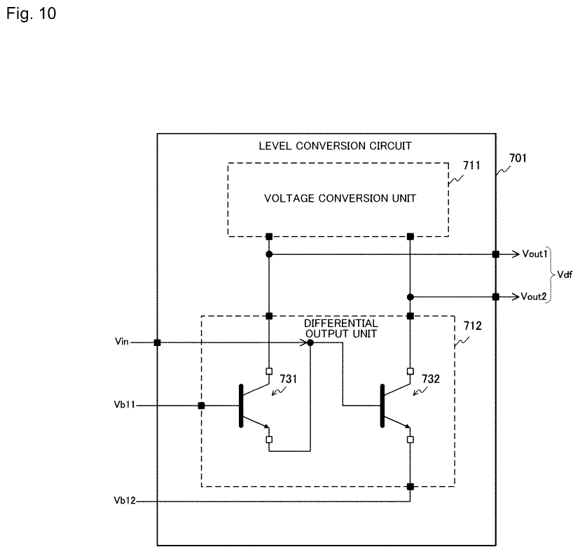

FIG. 10 illustrates an example of the configuration of a level conversion circuit according to a tenth embodiment.

In the drawing, a level conversion circuit 701 includes a voltage conversion unit 711 and a differential output unit 712. The differential output unit 712 generates a differential output Vdf on the basis of the same input signal Vin.

The differential output unit 712 includes two transistors 731, 732. The transistors 731, 732 are npn bipolar transistors. The transistor 731 outputs an output signal Vout1 on the basis of the input signal Vin. The transistor 732 receives the input signal Vin as an input, and outputs an output signal Vout2 on the basis of a bias that causes the transistor 732 to operate in a complementary manner with respect to the transistor 731. The term “complementary” as used herein indicates a relationship in which the collector current of the transistor 732 decreases in accordance with an increase in the collector current of the transistor 731, and in which the collector current of the transistor 732 increases in accordance with a decrease in the collector current of the transistor 731, for example.

At this time, the transistor 731 may generate a transconductance in the reverse polarity with respect to the input signal Vin using the input signal Vin as an input. The transistor 732 may generate a transconductance in the same polarity as the input signal Vin using the input signal Vin as an input.

In order to render the polarities of the transconductances generated by the transistors 731, 732 different from each other, it is possible to input the input signal Vin to different types of terminals, among terminals of the transistors 731, 732 for determining a threshold voltage. For example, the input signal Vin may be input to the emitter of the transistor 731, and the input signal Vin may be input to the base of the transistor 732.

The term “transconductance” as used herein indicates variations in the collector current with respect to variations in a base-emitter voltage Vbe of the transistor 731, 732. With a transconductance in the reverse polarity, the collector current decreases when the base-emitter voltage Vbe increases, and the collector current increases when the base-emitter voltage Vbe decreases. With a transconductance in the same polarity, the collector current increases when the base-emitter voltage Vbe increases, and the collector current decreases when the base-emitter voltage Vbe decreases.

Here, the output signal Vout2 may be in the reverse polarity with respect to the output signal Vout1. For example, the output signal Vout1 may be an inverted signal, and the output signal Vout2 may be a non-inverted signal. At this time, the output signals Vout1, Vout2 may constitute the differential output Vdf.

The transistor 731 is still another example of the first transistor set forth in the claims. The transistor 732 is still another example of the second transistor set forth in the claims. The output signal Vout1 is still another example of the first output signal set forth in the claims. The output signal Vout2 is still another example of the second output signal set forth in the claims.

The emitter of the transistor 731 is connected to the base of the transistor 732, and the collectors of the transistors 731, 732 are connected to the voltage conversion unit 711. The input signal Vin is input to the emitter of the transistor 731 and the base of the transistor 732. A bias voltage Vb11 is input to the base of the transistor 731, and a bias voltage Vb12 is input to the emitter of the transistor 732. The output signal Vout1 is output from the collector of the transistor 731, and the output signal Vout2 is output from the collector of the transistor 732.

The collector of the transistor 731 is still another example of the first terminal set forth in the claims. The emitter of the transistor 731 is still another example of the second terminal set forth in the claims. The base of the transistor 731 is still another example of the first control terminal set forth in the claims. The collector of the transistor 732 is still another example of the third terminal set forth in the claims. The emitter of the transistor 732 is still another example of the fourth terminal set forth in the claims. The base of the transistor 732 is still another example of the second control terminal set forth in the claims.

The bias voltages Vb11, Vb12 may be set such that the base-emitter voltages Vbe at the time of generation of a transconductance of the transistors 731, 732 are equal to each other.

At this time, when the transistor 731 receives the input signal Vin as an input, the transistor 731 may generate an output signal Vout1 in the opposite phase to the input signal Vin. When the transistor 732 receives the input signal Vin as an input, the transistor 732 may generate an output signal Vout2 in the same phase as the input signal Vin.

The voltage conversion unit 711 converts the level of the differential output Vdf generated by the differential output unit 712. At this time, the voltage conversion unit 711 may shift the level of the output signal Vout1 by converting a current based on the transconductance of the transistor 731 into a voltage. The voltage conversion unit 711 may shift the level of the output signal Vout2 by converting a current based on the transconductance of the transistor 732 into a voltage. The voltage conversion unit 711 may be composed of bipolar transistors, or may be composed of field effect transistors.

The collector currents of the transistors 731, 732 vary in a complementary manner on the basis of the input signal Vin. The differential output Vdf obtained by shifting the level of the input signal Vin and obtaining a differential for the input signal Vin is generated by the voltage conversion unit 711 operating on the basis of complementary variations in the collector currents of the transistors 731, 732.

In this manner, with the tenth embodiment discussed above, it is possible to generate the differential output Vdf without generating an inverted input from a non-inverted input, also when npn bipolar transistors are used as the transistors 731, 732.

The same configuration as the third embodiment discussed above may be used when the input signal Vin is at a CMOS level when the differential output unit 712 is composed of npn bipolar transistors. The same configuration as any of the fourth, seventh, and eighth embodiments discussed above may be used when the input signal Vin is at a level other than a CMOS level when the differential output unit 712 is composed of npn bipolar transistors. The same configuration as the fourth embodiment discussed above may be used when the input signal Vin is at a CMOS level when the differential output unit is composed of pnp bipolar transistors. The same configuration as the fifth embodiment discussed above may be used when the input signal Vin is at a level other than a CMOS level when the differential output unit is composed of pnp bipolar transistors. At this time, it is only necessary that the emitter, base, and collector of the bipolar transistors should be replaced with the source, gate, and drain, respectively, of the field effect transistors.

### 11. Eleventh Embodiment

While the level conversion circuit 101 is constituted using the differential output unit 112 and the voltage conversion unit 111 in the first embodiment discussed above, an interface circuit 840 is constituted using level conversion circuits 841 to 844 in an eleventh embodiment.

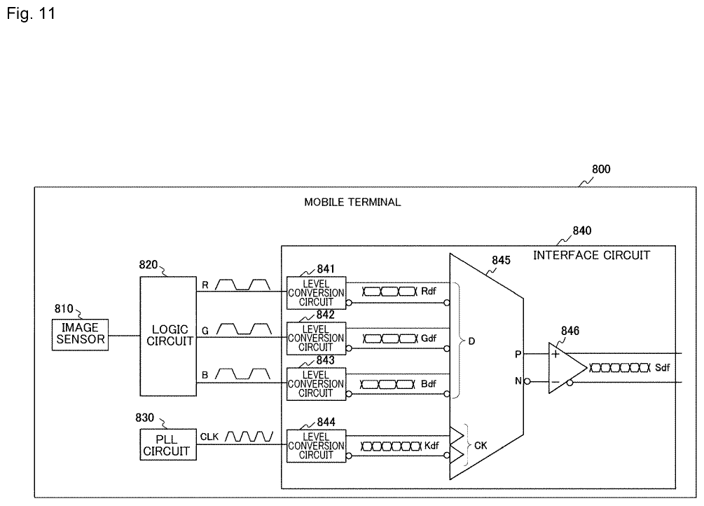

FIG. 11 is a block diagram illustrating an example of the configuration of an interface circuit according to an eleventh embodiment.

In the drawing, a mobile terminal 800 includes an image sensor 810, a logic circuit 820, a PLL (Phase Locked Loop) circuit 830, and an interface circuit 840. The image sensor 810 may be a CMOS (Complementary Metal Oxide Semiconductor) image sensor, or may be a CCD (Charge Coupled Device) image sensor. The PLL circuit 830 generates a clock signal CLK.

The logic circuit 820 converts an image signal output from the image sensor 810 so as to be compatible with the standard of the interface circuit 840. At this time, the logic circuit 820 generates video signals R, G, B on the basis of the image signal output from the image sensor 810, and inputs the video signals in parallel to the interface circuit 840.

The interface circuit 840 generates a serial output obtained by shifting the level of the parallel input and obtaining a differential for the parallel input. The interface circuit 840 includes level conversion circuits 841 to 844, a serializer 845, and a transmission driver 846.

Any of the level conversion circuits 101, 401, 601, 701 discussed above may be used as the level conversion circuits 841 to 844. The level conversion circuit 841 generates a differential output Rdf obtained by shifting the level of the video signal R. The level conversion circuit 842 generates a differential output Gdf obtained by shifting the level of the video signal G. The level conversion circuit 843 generates a differential output Bdf obtained by shifting the level of the video signal B. The level conversion circuit 844 generates a differential output Kdf obtained by shifting the level of the clock signal CLK. The differential output Kdf may have a clock frequency of 20 GHz or higher.

The serializer 845 serializes the differential outputs Rdf, Gdf, Bdf on the basis of clock synchronization according to the timing of the differential output Kdf. The serializer 845 includes a data input terminal D and a clock terminal CK. The data input terminal D supports three inputs, each supporting a non-inverted input and an inverted input. The clock terminal CK supports a non-inverted input and an inverted input.

The transmission driver 846 transmits a differential output Sdf serialized by the serializer 845 to the outside of the interface circuit 840. The differential output Sdf may be transferred at a rate of 40 Gbps or higher. In the mobile terminal 800, the differential output Sdf may be output to an application processor, for example.

While the interface circuit 840 is mounted on the mobile terminal 800 in the eleventh embodiment, the interface circuit 840 may be mounted on an electronic device or electronic equipment other than the mobile terminal 800. For example, the interface circuit 840 may be mounted on a server, a memory card, a USB (Universal Serial Bus) memory, etc. The standard of the interface circuit 840 may be MIPI (Mobile Industry Processor Interface), or may be other standards such as PCIe (Peripheral Component Interconnect Express) and Thunderbolt, for example.

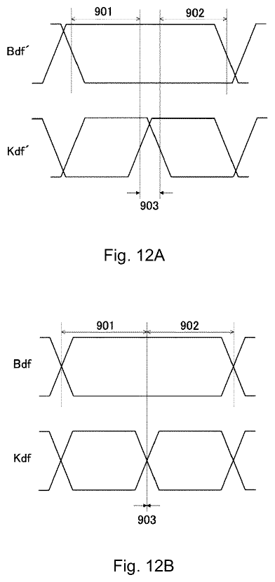

FIG. 12 illustrates a differential delay between a non-inverted output and an inverted output as compared with a comparative example. Symbol “a” in the drawing indicates waveforms of differential outputs generated when differential inputs are used, and symbol “b” in the drawing indicates waveforms of differential outputs Bdf, Kdf according to the eleventh embodiment discussed above.

When differential outputs are generated using differential inputs, inverted signals of a video signal B and a clock signal CLK are generated by inverting the video signal B and the clock signal CLK. Differential outputs Bdf, Kdf are generated using a non-inverted signal and an inverted signal of the video signal B and the clock signal CLK as differential inputs. At this time, as indicated by “a” in the drawing, a differential delay 903 is caused between a non-inverted output and an inverted output for each of the differential outputs Bdf, Kdf, decreasing margins of a setup period 901 and a hold period 902 of the differential output Bdf.

In the eleventh embodiment discussed above, on the other hand, a differential output Bdf is generated on the basis of the single video signal R, and a differential output Kdf is generated on the basis of the single clock signal CLK. At this time, it is not necessary to invert the video signal R and the clock signal CLK, in order to generate a differential output Bdf and a clock signal CLK, respectively. Therefore, as indicated by “b” in the drawing, no differential delay 903 is provided between a non-inverted output and an inverted output for each of the differential outputs Bdf, Kdf, increasing margins of the setup period 901 and the hold period 902 of the differential output Bdf.

In this manner, with the eleventh embodiment discussed above, it is possible to increase the speed of the interface circuit 840 and reduce the size, cost, and power consumption of the interface circuit 840 by constituting the interface circuit 840 using the level conversion circuits 841 to 844.

It should be noted that the above-described embodiments show examples for embodying the present technique, and matters in the embodiments and matters specifying the invention in the claims have a corresponding relationship with each other. Similarly, the matters specifying the invention in the claims and the matters having the same names in the embodiments of the present technique are correlated with each other. However, the present technology is not limited to the embodiments and can be embodied by applying various modifications to the embodiments without departing from the gist thereof. Furthermore, the effects described in the present specification are merely exemplary and not intended to be limited, and other effects may be provided as well.

The present technology can also have the following configurations.

(1) A transistor circuit including:
a first transistor that receives an input signal as an input and that outputs a first output signal; and
a second transistor that receives the input signal as an input and that outputs a second output signal, which is in a reverse polarity with respect to the first output signal, on the basis of a bias that causes the second transistor to operate in a complementary manner with respect to the first transistor.

(2) The transistor circuit according to 1 above, in which the first output signal and the second output signal are differential output signals.

(3) The transistor circuit according to 1 or 2 above, in which:
the first transistor includes a first terminal, a second terminal, and a first control terminal that controls a current that flows between the first terminal and the second terminal;
the second transistor includes a third terminal, a fourth terminal, and a second control terminal that controls a current that flows between the third terminal and the fourth terminal;
the first output signal is output from the first terminal;
the second output signal is output from the third terminal; and
the input signal is input to the second terminal of the first transistor and the second control terminal of the second transistor.

(4) The transistor circuit according to 3 above, further including a voltage conversion circuit that includes a first input terminal that receives the first output signal as an input and a second input terminal that receives the second output signal as an input, the voltage conversion circuit converting a current based on a transconductance of the first terminal into a voltage to output the voltage from the first input terminal, and converting a current based on a transconductance of the second transistor into a voltage to output the voltage from the second input terminal.

(5) The transistor circuit according to 3 or 4 above, in which:
the first terminal and the third terminal are each a drain of a field effect transistor or a collector of a bipolar transistor;
the first control terminal and the second control terminal are each a gate of the field effect transistor or a base of the bipolar transistor; and
the second terminal and the fourth terminal are each a source of the field effect transistor and an emitter of the bipolar transistor.

(6) The transistor circuit according to any one of 3 to 5 above, further including a first bias circuit that biases the first control terminal of the first transistor and the fourth terminal of the second transistor such that a voltage between the second terminal and the first control terminal at a time of generation of a transconductance of the first transistor and a voltage between the fourth terminal and the second control terminal at a time of generation of a transconductance of the second transistor are equal to each other.

(7) The transistor circuit according to any one of 3 to 6 above, in which the first transistor and the second transistor are field effect transistors, the transistor circuit further including a second bias circuit that biases a back gate of the first transistor and a back gate of the second transistor.

(8) The transistor circuit according to any one of 3 to 7 above, in which:
the first transistor and the second transistor are N-channel field effect transistors or npn bipolar transistors;
the input signal is given at a CMOS (Complementary Metal Oxide Semiconductor) level between a first ground potential and a first power supply potential; and
the first control terminal is connected to the first power supply potential, and the fourth terminal is connected to a second ground potential.

(9) The transistor circuit according to any one of 3 to 7 above, in which:
the first transistor and the second transistor are P-channel field effect transistors or pnp bipolar transistors;
the input signal is given at a CMOS level between a first ground potential and a first power supply potential; and
the first control terminal is connected to the first ground potential, and the fourth terminal is connected to a second power supply potential.

(10) The transistor circuit according to any one of 3 to 7 above, in which: the input signal is at a level other than a CMOS level; and the first control terminal and the fourth terminal are connected to a common potential.

(11) The transistor circuit according to 10 above, in which the common potential is variable.

(12) The transistor circuit according to 10 above, in which the common potential is generated on the basis of the input signal.

### REFERENCE SIGNS LIST

101, 401, 601, 701 Level conversion circuit
111, 411, 611, 711 Voltage conversion unit
112, 412, 612, 712 Differential output unit
131, 132, 431, 432, 631, 632, 731, 732 Transistor

1. A transistor circuit comprising:
a first transistor that receives an input signal as an input and that outputs a first output signal; and
a second transistor that receives the input signal as an input and that outputs a second output signal, which is in a reverse polarity with respect to the first output signal, on the basis of a bias that causes the second transistor to operate in a complementary manner with respect to the first transistor.

2. The transistor circuit according to claim 1, wherein
the first output signal and the second output signal are differential output signals.

3. The transistor circuit according to claim 1, wherein:
the first transistor includes a first terminal, a second terminal, and a first control terminal that controls a current that flows between the first terminal and the second terminal;
the second transistor includes a third terminal, a fourth terminal, and a second control terminal that controls a current that flows between the third terminal and the fourth terminal;
the first output signal is output from the first terminal;
the second output signal is output from the third terminal; and
the input signal is input to the second terminal of the first transistor and the second control terminal of the second transistor.

4. The transistor circuit according to claim 1, further comprising a voltage conversion circuit that includes a first input terminal that receives the first output signal as an input and a second input terminal that receives the second output signal as an input, the voltage conversion circuit converting a current based on a transconductance of the first terminal into a voltage to output the voltage from the first input terminal, and converting a current based on a transconductance of the second transistor into a voltage to output the voltage from the second input terminal.

5. The transistor circuit according to claim 3, wherein:
the first terminal and the third terminal are each a drain of a field effect transistor or a collector of a bipolar transistor;
the first control terminal and the second control terminal are each a gate of the field effect transistor or a base of the bipolar transistor; and
the second terminal and the fourth terminal are each a source of the field effect transistor and an emitter of the bipolar transistor.

6. The transistor circuit according to claim 3, further comprising a first bias circuit that biases the first control terminal of the first transistor and the fourth terminal of the second transistor such that a voltage between the second terminal and the first control terminal at a time of generation of a transconductance of the first transistor and a voltage between the fourth terminal and the second control terminal at a time of generation of a transconductance of the second transistor are equal to each other.

7. The transistor circuit according to claim 3, wherein the first transistor and the second transistor are field effect transistors, the transistor circuit further comprising a second bias circuit that biases a back gate of the first transistor and a back gate of the second transistor.

8. The transistor circuit according to claim 3, wherein:
the first transistor and the second transistor are N-channel field effect transistors or npn bipolar transistors;
the input signal is given at a CMOS (Complementary Metal Oxide Semiconductor) level between a first ground potential and a first power supply potential; and
the first control terminal is connected to the first power supply potential, and the fourth terminal is connected to a second ground potential.

9. The transistor circuit according to claim 3, wherein:
the first transistor and the second transistor are P-channel field effect transistors or pnp bipolar transistors;
the input signal is given at a CMOS level between a first ground potential and a first power supply potential; and
the first control terminal is connected to the first ground potential, and the fourth terminal is connected to a second power supply potential.

10. The transistor circuit according to claim 3, wherein:
the input signal is at a level other than a CMOS level; and
the first control terminal and the fourth terminal are connected to a common potential.

11. The transistor circuit according to claim 10, wherein
the common potential is variable.

12. The transistor circuit according to claim 10, wherein
the common potential is generated on the basis of the input signal.
